(19) United States
(12) Patent Application Publication
(10) Pub. No.: US 2024/0369935 A1
(43) Pub. Date: Nov. 7, 2024

(54) COMPOSITION FOR REMOVING EDGE BEAD FROM METAL-CONTAINING RESISTS, AND METHOD OF FORMING PATTERNS INCLUDING STEP OF REMOVING EDGE BEAD USING SAME

(71) Applicant: SAMSUNG SDI CO., LTD., Yongin-si, Gyeonggi-do (KR)

(72) Inventors: Hyungrang MOON, Suwon-si (KR); Minyoung LEE, Suwon-si (KR); Ryunmin HEO, Suwon-si (KR); Jamin KU, Suwon-si (KR); Donghyung LEE, Suwon-si (KR); Dasom HAN, Suwon-si (KR); Minsoo KIM, Suwon-si (KR); Jaehyun KIM, Suwon-si (KR)

(21) Appl. No.: 18/565,488

(22) PCT Filed: Jul. 4, 2022
(86) PCT No.: PCT/KR2022/009603

§ 371 Date: Nov. 29, 2023

(30) Foreign Application Priority Data
Aug. 10, 2021 (KR) 10-2021-0105523
May 17, 2022 (KR) 10-2022-0060372

(51) Int. Cl. G03F 7/20; G03F 7/004; G03F 7/16

(52) U.S. Cl. CPC G03F 7/2028; G03F 7/0042; G03F 7/168

(57) ABSTRACT

Provided are composition for removing edge beads from metal-containing resists, and a method of forming patterns including step of removing edge beads using the same and the composition includes an organic solvent and a compound having an AMW of 7 g/mol·ea or more.

### TECHNICAL FIELD

This disclosure relates to a composition for removing edge beads from metal-containing resists, and a method of forming patterns including step of removing edge beads using the same.

### BACKGROUND ART

In recent years, a semiconductor industry has been accompanied by a continuous reduction of critical dimensions, and this dimensional reduction requires new types of high-performance photoresist materials and a patterning method that satisfy a demand for processing and patterning with increasingly smaller features.

In addition, with the recent rapid development of the semiconductor industry, a semiconductor device is required of an operation speed and large storage capacity, and in line with this requirement, process technology for improving integration, reliability, and a response speed of the semiconductor device is being developed. Particularly, it is important to accurately control/implant impurities in working regions of a silicon substrate and to interconnect these regions to form a device and an ultra-high-density integrated circuit, which may be achieved by a photolithographic process. In other words, it is important to integrate the photolithographic process including coating a photoresist on the substrate, selectively exposing it to ultraviolet (UV) (including extreme ultraviolet (UV)), electron beams, X rays, or the like, and then, developing it.

Particularly, in the process of forming the photoresist layer, the resist is coated on the substrate, mainly while rotating the silicon substrate, wherein the resist is coated on an edge and rear surface of the substrate, which may cause indentation or pattern defects in the subsequent semiconductor processes such as etching and ion implantation processes. Accordingly, a process of stripping and removing the photoresist coated on the edge and rear surface of the silicon substrate by using a thinner composition, that is, an EBR (edge bead removal) process is performed. The EBR process requires a composition that exhibits excellent solubility for the photoresist and effectively removes beads and the photoresist remaining in the substrate and generates no resist residue.

### DISCLOSURE

### Technical Problem

An embodiment provides a composition for removing edge beads from metal-containing resists.

Another embodiment provides a method of forming patterns including step of removing edge beads using the composition.

### Technical Solution

A composition for removing edge beads from metal-containing resists according to an embodiment includes an organic solvent and a compound having an AMW of 7 g/mol·ea or more.

The AMW is obtained by dividing a total molecular weight of the compound by the number of atoms, assuming that the types of atoms included in the compound are all the same.

That is, it can be expressed as AMW=molecular weight/number of atoms (g/mol·ea).

$$The A M W may be 7 g / mol \cdot ea \leq A M W \leq 50 g / mol \cdot ea .$$

The compound having the AMW of 7 g/mol·ea or more may include pyrocatechol, vinylphosphonic acid, 4-chlorocatechol, glycolic acid, 4-methyl catechol, tropolone, oxalic acid, 4-nitrocatechol, acetohydroxamic acid, butylphosphonic acid, or a combination thereof.

The composition for removing edge beads from metal-containing resists may include 50 to 99.99 wt % of the organic solvent; and 0.01 to 50 wt % of the compound having the AMW of 7 g/mol·ea or more.

The metal compound included in the metal-containing resists may include at least one of an alkyl tin oxo group and an alkyl tin carboxyl group.

The metal compound included in the metal-containing resists may be represented by Chemical Formula 1.

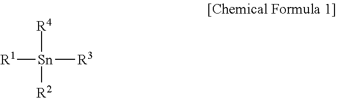

In Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group and R^{b} is a substituted or unsubstituted C1 to C20 alkyl group),
R² to R⁴ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

A method of forming patterns according to another embodiment includes coating a metal-containing resist composition on a substrate, coating the aforementioned composition for removing edge beads from the metal-containing resists along an edge of the substrate, drying and heating a coated resultant to form a metal-containing resist film on the substrate, and exposing and developing a dried and heated resultant to form a resist pattern.

The method of forming patterns may further include coating the aforementioned composition for removing edge beads from the metal-containing resists and washing the same along the edge of the substrate to remove edge beads, after exposing and developing.

### Advantageous Effects

The composition for removing edge beads from the metal-containing resists according to an embodiment reduces the metal-based contamination inherent in the metal-containing resists and removes the resist coated on the edge and the rear surface of the substrate, thereby satisfying requirements of processing and patterning of smaller features.

### DESCRIPTION OF THE DRAWINGS

FIG. 1 is a schematic view of a photoresist coating apparatus.

<Description of symbols>

| | |
|---|---|
| 1: substrate support portion | 2: spray nozzle |
| 10: photoresist solution | 12: edge bead |

### BEST MODE

Hereinafter, embodiments of the present invention are described in detail with reference to the accompanying drawings. In the following description of the present disclosure, the well-known functions or constructions will not be described in order to clarify the present disclosure.

In order to clearly illustrate the present disclosure, the description and relationships are omitted, and throughout the disclosure, the same or similar configuration elements are designated by the same reference numerals. Also, since the size and thickness of each configuration shown in the drawing are arbitrarily shown for better understanding and ease of description, the present disclosure is not necessarily limited thereto.

In the drawings, the thickness of layers, films, panels, regions, etc., are exaggerated for clarity. In the drawings, the thickness of a part of layers or regions, etc., is exaggerated for clarity. It will be understood that when an element such as a layer, film, region, or substrate is referred to as being “on” another element, it can be directly on the other element or intervening elements may also be present.

In the present disclosure, “substituted” refers to replacement of a hydrogen atom by deuterium, a halogen group, a hydroxyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a cyano group. “Unsubstituted” means that a hydrogen atom remains as a hydrogen atom without being replaced by another substituent.

In the present disclosure, the term “alkyl group” means a linear or branched aliphatic hydrocarbon group, unless otherwise defined. The alkyl group may be a “saturated alkyl group” that does not contain any double or triple bonds.

The alkyl group may be a C1 to C20 alkyl group. More specifically, the alkyl group may be a C1 to C10 alkyl group or a C1 to C6 alkyl group. For example, a C1 to C4 alkyl group means that the alkyl chain contains 1 to 4 carbon atoms, and may be selected from methyl, ethyl, propyl, iso-propyl, n-butyl, iso-butyl, sec-butyl, and t-butyl.

Specific examples of the alkyl group include a methyl group, an ethyl group, a propyl group, an isopropyl group, a butyl group, an isobutyl group, a t-butyl group, a pentyl group, a hexyl group, a cyclopropyl group, a cyclobutyl group, a cyclopentyl group, a cyclohexyl group, etc.

In the present disclosure, when a definition is not otherwise provided, the term “cycloalkyl group” refers to a monovalent cyclic aliphatic hydrocarbon group.

In the present disclosure, when a definition is not otherwise provided, the term “alkenyl group” is a linear or branched aliphatic hydrocarbon group, and refers to an aliphatic unsaturated alkenyl group containing one or more double bonds.

In the present disclosure, when a definition is not otherwise provided, the term “alkynyl group” is a linear or branched aliphatic hydrocarbon group, and refers to an unsaturated alkynyl group containing one or more triple bonds.

In the present disclosure, “aryl group” means a substituent in which all elements of a cyclic substituent have p-orbitals, and these p-orbitals form a conjugate and may include monocyclic or fused ring polycyclic (i.e., rings that share adjacent pairs of carbon atoms) functional groups.

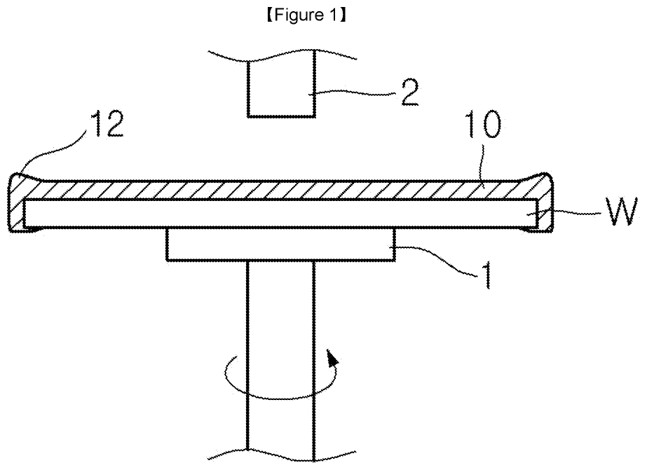

FIG. 1 is a schematic view of a photoresist coating apparatus.

Referring to FIG. 1, a substrate support portion 1 on which a substrate W is placed is provided, and the substrate support portion 1 includes a spin chuck or a spin coater.

The substrate support portion 1 rotates in a first direction at a predetermined rotation speed, and provides a centrifugal force to the substrate W. A spray nozzle 2 is disposed on the substrate support portion 1, and the spray nozzle 2 is located in an atmospheric area deviating from the upper portion of the substrate W and moves to the upper portion of the substrate during the solution supply step to spray a photoresist solution 10. Accordingly, the photoresist solution 10 is coated on the surface of the substrate by the centrifugal force. At this time, the photoresist solution 10 supplied to the center of the substrate W is coated while being spread to the edge of the substrate W by centrifugal force, and a portion thereof is moved to the side surface of the substrate and the lower surface of the edge of the substrate.

That is, in the coating process, the photoresist solution 10 is mainly coated by a spin coating method. By supplying a predetermined amount of viscous photoresist solution 10 to the center of the substrate W, it gradually spreads toward the edge of the substrate by centrifugal force.

Therefore, the thickness of the photoresist is formed to be flat by the rotation speed of the substrate support portion.

However, as the solvent evaporates, the viscosity gradually increases, and a relatively large amount of photoresist is accumulated on the edge of the substrate by the action of surface tension. More seriously, photoresist is accumulated up to the lower surface of the edge of the substrate, which is referred to as edge beads 12.

Hereinafter, a composition for removing edge beads from metal-containing resists according to an embodiment is described.

The composition for removing edge beads from the metal-containing resists according to an embodiment of the present invention includes an organic solvent, and a compound having an AMW of 7 g/mol·ea or more.

The AMW is obtained by dividing a total molecular weight of the compound by the number of atoms, assuming that the types of atoms included in the compound are all the same.

That is, assuming that the types of atoms are all the same, an increase in AMW means that a relatively large number of oxygen atoms, nitrogen atoms, sulfur atoms, etc., which are heavier than carbon atoms, are included, and hydrophilicity of the molecules is relatively high, and these are highly likely to form polar-bonds to the photoresist mainly by lone pairs of electrons, etc. On the other hand, when the AMW becomes smaller, a relatively large number of carbon atoms and lighter hydrogen atoms are included, which mainly prefer covalent bonds rather than polar bonds, hydrophobicity of the molecule is relatively high, and probability of bonding to the photoresist is low.

According to an embodiment, in the case of the compound having the AMW of 7 g/mol·ea or more, it becomes weakly hydrophilic in an organic solvent and easily coordinates to a metal, for example, Sn, of a metal-containing resist, thereby contributing to lowering the residual amount of Sn.

Specifically, the AMW may be desirably 7 g/mol·ea≤AMW≤50 g/mol·ea, and more specifically, 7 g/mol·ea≤AMW≤30 g/mol·ea. Within the above range, the residual amount of Sn may be lowered and at the same time an appropriate solubility in an organic solvent may be provided.

For example, the compound having the AMW of 7 g/mol·ea or more may include pyrocatechol, vinylphosphonic acid, 4-chlorocatechol, glycolic acid, 4-methyl catechol, tropolone, oxalic acid, 4-nitrocatechol, acetohydroxamic acid, butylphosphonic acid, or a combination thereof, but is not limited thereto.

In an example embodiment, the composition for removing edge beads from metal-containing resists may include 50 to 99.99 wt % of the organic solvent and 0.01 to 50 wt % of the aforementioned compound having the AMW of 7 g/mol·ea or more.

In a specific embodiment, the composition for removing edge beads from metal-containing resists may include the aforementioned compound having the AMW of 7 g/mol·ea or more in an amount of 0.05 to 40 wt %, specifically 0.5 to 30 wt %, or more specifically 1 to 20 wt %.

The organic solvent included in the composition for removing edge beads from the metal-containing resists according to an embodiment may be for example propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, cyclohexanone, gamma butyrolactone (GBL), 1-butanol (n-butanol), ethyl lactate (EL), diene butylether (DBE), diisopropyl ether (DIAE), acetylacetone, 4-methyl-2-pentenol (or referred to as methyl isobutyl carbinol (MIBC)), 1-methoxy-2-propanol, 1-ethoxy-2-propanol, toluene, xylene, methylethylketone, cyclopentanone, cyclohexanone, 2-hydroxyethyl propionate, 2-hydroxy-2-methylethyl propionate, ethoxyethyl acetate, hydroxyethyl acetate, 2-hydroxy-3-methylmethyl butanoate, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, ethyl lactate, butyl lactate(n-butylactate), methyl-2-hydroxyisobutyrate(HBM), methoxy benzene, n-butyl acetate, 1-methoxy-2-propyl acetate, methoxyethoxy propionate, ethoxyethoxy propionate, or a mixture thereof, but is not limited thereto.

The composition for removing edge beads from the metal-containing resists according to the present invention may be particularly effective in removing metal-containing resists, more specifically undesirable metal residues such as tin-based metal residues.

The metal compound included in the metal-containing resists may include at least one of an alkyl tin oxo group and an alkyl tin carboxyl group.

For example, the metal compound included in the metal-containing resists may be represented by Chemical Formula 1.

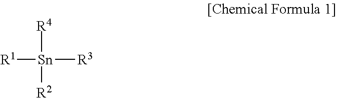

In Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group, and R^{b} is a substituted or unsubstituted C1 to C20 alkyl group),
R² to R⁴ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

Meanwhile, according to another embodiment, a method of forming patterns includes the step of removing the edge beads using the aforementioned composition for removing edge beads from the metal-containing resist. For example, the manufactured pattern may be a photoresist pattern. More specifically, it may be a negative type photoresist pattern.

The method of forming patterns according to an embodiment includes coating a metal-containing resist composition on a substrate, coating the aforementioned composition for removing edge beads from the metal-containing resists along an edge of the substrate, drying and heating a coated resultant to form a metal-containing resist film on the substrate, and exposing and developing a dried and heated resultant to form a resist pattern.

More specifically, the forming of patterns using the metal-containing resist composition may include coating a metal-containing resist composition on a substrate on which a thin film is formed by spin coating, slit coating, inkjet printing, etc., and drying the coated metal-containing resist composition to form a photoresist film. The metal-containing resist composition may include a tin-based compound, for example, the tin-based compound may include at least one of an alkyl tin oxo group and an alkyl tin carboxyl group.

Subsequently, the step of coating the aforementioned composition for removing edge beads from metal-containing resists may be performed, and more specifically, the composition for removing edge beads from the metal-containing resists along the edge of the substrate may be coated while rotating the substrate at an appropriate speed (e.g., 500 rpm or more).

Subsequently, a first heat treatment process of heating the substrate on which the photoresist film is formed is performed. The first heat treatment process may be performed at a temperature of about 80° C. to about 120° C. and in this process, the solvent is evaporated and the photoresist film may be more firmly adhered to the substrate.

And the photoresist film is selectively exposed.

For example, examples of light that may be used in the exposure process may include not only light having a short wavelength such as i-line (wavelength 365 nm), KrF excimer laser (wavelength 248 nm), ArF excimer laser (wavelength 193 nm), but also EUV (light having a high energy wavelength such as EUV (Extreme UltraViolet, wavelength 13.5 nm), E-Beam (electron beam), etc.

More specifically, the light for exposure according to an embodiment may be short-wavelength light having a wavelength range of about 5 nm to about 150 nm, and light having a high energy wavelength such as EUV (Extreme UltraViolet, wavelength 13.5 nm), E-Beam (electron beam), etc.

In the step of forming the photoresist pattern, a negative type pattern may be formed.

The exposed region of the photoresist film has a solubility different from that of the unexposed region of the photoresist film as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist film becomes difficult to be dissolved in a developing solution.

Specifically, the photoresist pattern corresponding to the negative tone image may be completed by dissolving and removing the photoresist film corresponding to the unexposed region using an organic solvent such as 2-heptanone.

The developing solution used in the method of forming patterns according to the embodiment may be an organic solvent, for example, ketones such as methyl ethyl ketone, acetone, cyclohexanone, or 2-haptanone, alcohols such as 4-methyl-2-propanol, 1-butanol, isopropanol, 1-propanol, or methanol, esters such as propylene glycol monomethyl ether acetate, ethyl acetate, ethyl lactate, n-butyl acetate, butyrolactone, aromatic compounds such as benzene, xylene, or toluene, or a combination thereof.

In addition, the method of forming patterns may further include coating the composition for removing edge beads from the metal-containing resists after the exposing and developing. Specifically, the method may include coating an appropriate amount of the composition for removing edge beads from the metal-containing resists along the edge of the substrate while rotating the substrate at an appropriate speed (e.g., 500 rpm or more).

As described above, the photoresist pattern formed by exposure to not only light having a wavelength such as i-line (wavelength 365 nm), KrF excimer laser (wavelength 248 nm), ArF excimer laser (wavelength 193 nm), but also EUV (Extreme UltraViolet; wavelength 13.5 nm), but also light having high energy such as an E-beam (electron beam) may have a thickness width of about 5 nm to about 100 nm. For example, the photoresist pattern may be formed to have a thickness width of 5 nm to 90 nm, 5 nm to 80 nm, 5 nm to 70 nm, 5 nm to 60 nm, 5 nm to 50 nm, 5 nm to 40 nm, 5 nm to 30 nm, or 5 nm to 20 nm.

On the other hand, the photoresist pattern may have a pitch having a half-pitch of less than or equal to about 50 nm, for example less than or equal to 40 nm, for example less than or equal to 30 nm, for example less than or equal to 20 nm, for example less than or equal to 15 nm and a line width roughness of less than or equal to about 10 nm, less than or equal to about 5 nm, less than or equal to about 3 nm, or less than or equal to about 2 nm.

### MODE FOR INVENTION

Hereinafter, the present invention will be described in more detail through examples relating to the preparation of the aforementioned composition for removing edge beads from metal-containing resists. However, the technical features of the present invention are not limited by the following examples.

### Preparation Example: Preparation of Organometal-Containing Photoresist Composition

An organometallic compound having a structure of Chemical Formula C was dissolved at a concentration of 1 wt % in 4-methyl-2-pentanol and then, filtered through a 0.1 μm PTFE syringe filter, obtaining a photoresist composition.

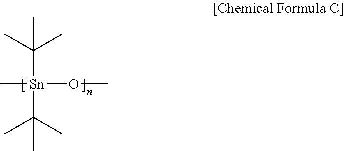

### Evaluation: Tin (Sn) Residual Amount

1.0 mL of the photoresist composition according to Preparation Example was put on a 4-inch silicon wafer, left still for 20 seconds, and spin-coated at a speed of 1,500 rpm for 30 seconds. 6.5 mL of each of the compositions for removing edge beads according to Examples 1 to 10 and Comparative Examples 1 to 9 described in Table 1 was added along the edge on the wafer on which the coating film was formed, spin-coated for 3 seconds, and while rotating at a speed of 1,500 rpm, dried for 25 seconds. The processes of adding the composition for removing the edge beads, spin coating, and drying were repeated three times. Then, the resultant was heat-treated at 150° C. for 60 seconds and the Sn amount was confirmed through VPD ICP-MS analysis.

TABLE 1

| | Composition for removing | | | Sn |
|---|---|---|---|---|
| | edge beads from the metal- | | | residual |
| | containing resists | | AMW | amount |
| | Compound | Solvent | (g/mol · | (×10¹⁰ |
| | (10 wt %) | (90 wt %) | ea) | atoms/cm²) |
| Example 1 | Pyrocatechol | PGMEA | 7.87 | 420 |
| Example 2 | Vinylphosphonic acid | PGMEA | 9.82 | 26 |
| Example 3 | 4-chlorocatechol | PGMEA | 10.33 | 32 |
| Example 4 | Glycolic acid | PGMEA | 8.45 | 220 |
| Example 5 | 4-methyl catechol | PGMEA | 7.30 | 360 |
| Example 6 | Tropolone | PGMEA | 8.14 | 8 |
| Example 7 | Acetohydroxamic acid | PGMEA | 7.51 | 477 |
| Example 8 | 4-Nitrocatechol | PGMEA | 8.14 | 8 |
| Example 9 | Oxalic acid | PGMEA | 11.26 | 150 |
| Example 10 | Butylphosphonic acid | PGMEA | 7.27 | 150 |
| Comparative | Ethanolamine | PGMEA | 5.56 | 2,000 |
| Example 1 | | | | |
| Comparative | 2-Amino-2-ethyl-1,3- | PGMEA | 5.68 | 2,100 |
| Example 2 | propanediol | | | |
| Comparative | 1,2-propanediol | PGMEA | 5.86 | 2,900 |
| Example 3 | | | | |
| Comparative | 1,3-propanediol | PGMEA | 5.86 | 3,000 |
| Example 4 | | | | |
| Comparative | Benzene-1,2-diamine | PGMEA | 6.76 | 3,500 |
| Example 5 | | | | |
| Comparative | Ethyl 2- | PGMEA | 6.29 | 3,500 |
| Example 6 | hydroxybutanoate | | | |
| Comparative | Glycerol | PGMEA | 6.58 | 3,700 |
| Example 7 | | | | |
| Comparative | Propylene glycol | PGMEA | 5.37 | 4,600 |
| Example 8 | propyl ether | | | |
| Comparative | Acetone oxime | PGMEA | 6.09 | 4,900 |
| Example 9 | | | | |

Referring to Table 1, the composition for removing the edge beads from the metal-containing resists according to Examples 1 to 10 exhibited more improved metal removal effect compared with the composition for removing the edge beads from the metal-containing resists according to Comparative Examples 1 to 9, and further promoted reduction of residual metals.

Hereinbefore, the certain embodiments of the present invention have been described and illustrated, however, it is apparent to a person with ordinary skill in the art that the present invention is not limited to the embodiment as described, and may be variously modified and transformed without departing from the spirit and scope of the present invention. Accordingly, the modified or transformed embodiments as such may not be understood separately from the technical ideas and aspects of the present invention, and the modified embodiments are within the scope of the claims of the present invention.

1. A composition for removing edge beads from metal-containing resists, comprising
an organic solvent, and
a compound having an AMW of 7 g/mol·ea or more.
wherein the AMW is obtained by dividing a total molecular weight of the compound by the number of atoms, assuming that the types of atoms included in the compound are all the same.

2. The composition of claim 1, wherein the AMW is 7 g/mol·ea≤AMW≤50 g/mol·ea.

3. The composition of claim 1, wherein the compound having the AMW of 7 g/mol·ea or more includes pyrocatechol, vinylphosphonic acid, 4-chlorocatechol, glycolic acid, 4-methyl catechol, tropolone, oxalic acid, 4-nitrocatechol, acetohydroxamic acid, butylphosphonic acid, or a combination thereof.

4. The composition of claim 1, wherein the composition includes 50 to 99.99 wt % of the organic solvent; and
0.01 to 50 wt % of the compound having the AMW of 7 g/mol·ea or more.

5. The composition of claim 1, wherein a metal compound included in the metal-containing resists includes at least one of an alkyl tin oxo group and an alkyl tin carboxyl group.

6. The composition of claim 1, wherein
a metal compound included in the metal-containing resists is represented by Chemical Formula 1: 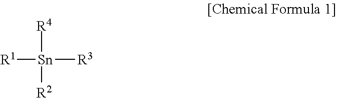
wherein, in Chemical Formula 1,
R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and —R^{a}—O—R^{b} (wherein R^{a} is a substituted or unsubstituted C1 to C20 alkylene group and R^{b} is a substituted or unsubstituted C1 to C20 alkyl group),
R² to R⁴ are each independently selected from —OR^{c} or —OC(═O)R^{d},
R^{c} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{d} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

7. A method of forming patterns, comprising
coating a metal-containing resist composition on a substrate;
coating the aforementioned composition for removing an edge beads from the metal-containing resists of claim 1 along an edge of the substrate;
drying and heating a coated resultant to form a metal-containing resist film on the substrate; and
exposing and developing a dried and heated resultant to form a resist pattern.

8. The method of claim 7, wherein the composition for removing edge beads from the metal-containing resists is coated along an edge of the substrate again after exposing and developing.
